(19) United States
(12) Patent Application Publication
(10) Pub. No.: US 2009/0135951 A1
(43) Pub. Date: May 28, 2009

(54) METHOD AND APPARATUS FOR POWER CONTROL TECHNIQUES IN AN OFDM BASED RECEIVER

(75) Inventor: DINESH VENKATACHALAM, FREMONT, CA (US)

Correspondence Address: FRANK F. TIAN, 331-4A THIRD AVENUE, LONG BEACH, NJ, 07740, US

(73) Assignee: LEGEND SILICON CORP, FREMONT, CA (US)

(21) Appl. No.: 11/946,808

(22) Filed: Nov. 28, 2007

(51) Int. Cl. H03K 9/00; H04L 27/00; H04L 7/00

(52) U.S. Cl. 375/316; 375/354; 375/260

(57) ABSTRACT

A method comprising the steps of: providing a receiver based on synchronous, sequential, digital design techniques, wherein the receiver is subdivided into stages or sub-devices; providing a primary reset, which initializes the receiver to a known state; and providing a primary clock for changing the known state based on other inputs to the receiver. An OFDM receiver comprising: a primary reset, which initializes the receiver to a known state; and a primary clock for changing the known state based on other inputs to the receiver, wherein the receiver is divided into a plurality of sub-devices forming a sequential device; and a control signal for overriding the primary clock and holding a plurality sequential elements in a reset state.

### FIELD OF THE INVENTION

The present invention relates generally to orthogonal frequency division multiplexing (OFDM) based receivers, more specifically the present invention relates to method and apparatus for improved power control techniques in an OFDM based receiver.

### BACKGROUND

It is essential to reduce the power consumption for OFDM based receiver to extend the battery life in mobile applications, and extend the range of operating conditions for both fixed and mobile devices.

Therefore, improved method and apparatus for power control techniques in an OFDM based receiver is desired.

### SUMMARY OF THE INVENTION

An improved method and apparatus for power control techniques in an OFDM based receiver are provided.

A method comprising the steps of: providing a receiver based on synchronous, sequential, digital design techniques, wherein the receiver is subdivided into stages or sub-devices; providing a primary reset, which initializes the receiver to a known state; and providing a primary clock for changing the known state based on other inputs to the receiver.

An OFDM receiver comprising: a primary reset, which initializes the receiver to a known state; and a primary clock for changing the known state based on other inputs to the receiver, wherein the receiver is divided into a plurality of sub-devices forming a sequential device; and a control signal for overriding the primary clock and holding a plurality sequential elements in a reset state.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a process in accordance with some embodiments of the invention.

FIG. 2 is an example of a first block diagram in accordance with some embodiments of the invention.

FIG. 3 is an example of a second block diagram in accordance with some embodiments of the invention.

FIG. 3A is a time line of FIG. 3.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to improved power saving method and apparatus in an OFDM receiver. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain mixed-signal, sequential and combinational logic circuits, some, most, or all of the functions of improved power saving method and apparatus in an OFDM receiver. The non-processor circuits may include, but are not limited to, a radio receiver, a radio transmitter, signal drivers, clock circuits, power source circuits, and user input devices. As such, these functions may be interpreted as steps of a method to perform improved power saving method and apparatus in an OFDM receiver. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

Dynamic Power dissipation in a device may be formulated as follows P=C×V×f; where C is the capacitive load, V is the voltage level and f is the frequency of operation. Improved power savings can be achieved by any or a combination of the following methods.

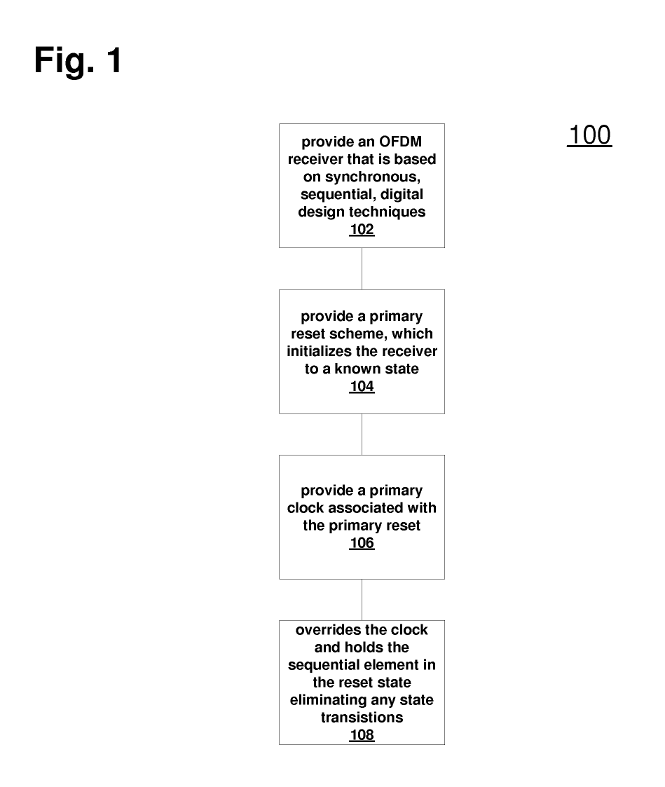

Referring to FIG. 1, a flowchart 100 depicting a power control method for an OFDM receiver based on synchronous, sequential, digital design at a system level is shown. An OFDM receiver is based on synchronous, sequential, digital design techniques is provided (Step 102). Synchronous, sequential, digital designs rely on underlying silicon CMOS transistor technology designed using process rules that are based on specific voltage and current requirement. In the OFDM receiver, a primary reset, which initializes the design or the receiver system to a known state, is provided (Step 104). A primary clock used for changing the state based on other inputs to the sequential device is provided (Step 106). The primary reset when activated overrides the clock and holds the sequential element in the reset state by eliminating any state transitions, thereby reducing dynamic power (Step 108). As can be seen, the primary clock is overridden and the sequential element is hold in the reset state thereby eliminating the cost of state transition.

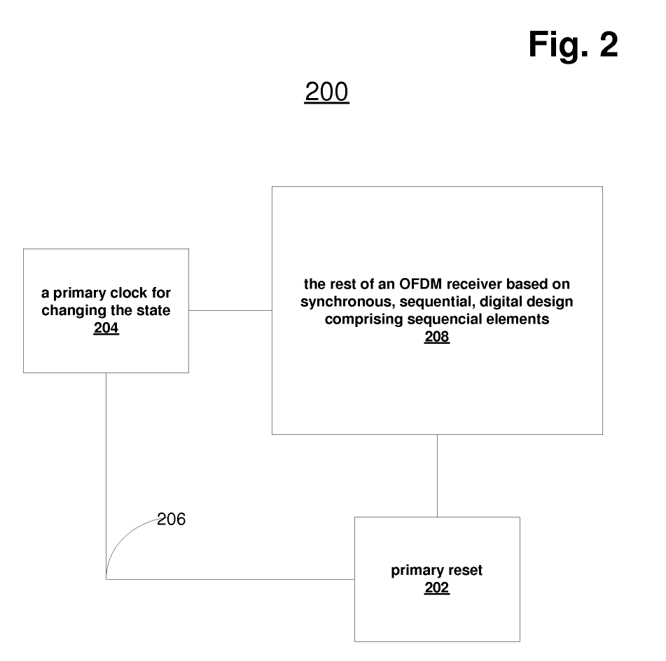

In the System level power control can be achieved as shown in FIG. 2. An OFDM receiver 200 is provided that is based on synchronous, sequential, digital design techniques. Synchronous, sequential, digital designs 200 rely on electric Current and Voltage to allow a device such as receiver 200 to operate. In the OFDM receiver 200, a primary reset device or function 202 which initializes the design 200 to a known state is provided in association 206 with a primary clock 204 for changing the state. Power consumed by the receiver 200 can be categorized into active power and leakage power. Active power is the power consumed when the sequential elements 208 change states on the primary clock 204 transition. Leakage power is the power consumed during the non-active states. When power is supplied to the device, the primary reset 202 may be activated to overrides the clock 204 and hold the sequential element in the reset state eliminating any state Transitions, thereby reducing active power. Also, if the primary clock 204 does no transition, then the active power consumption can be eliminated as long as clock 204 is held at a static state.

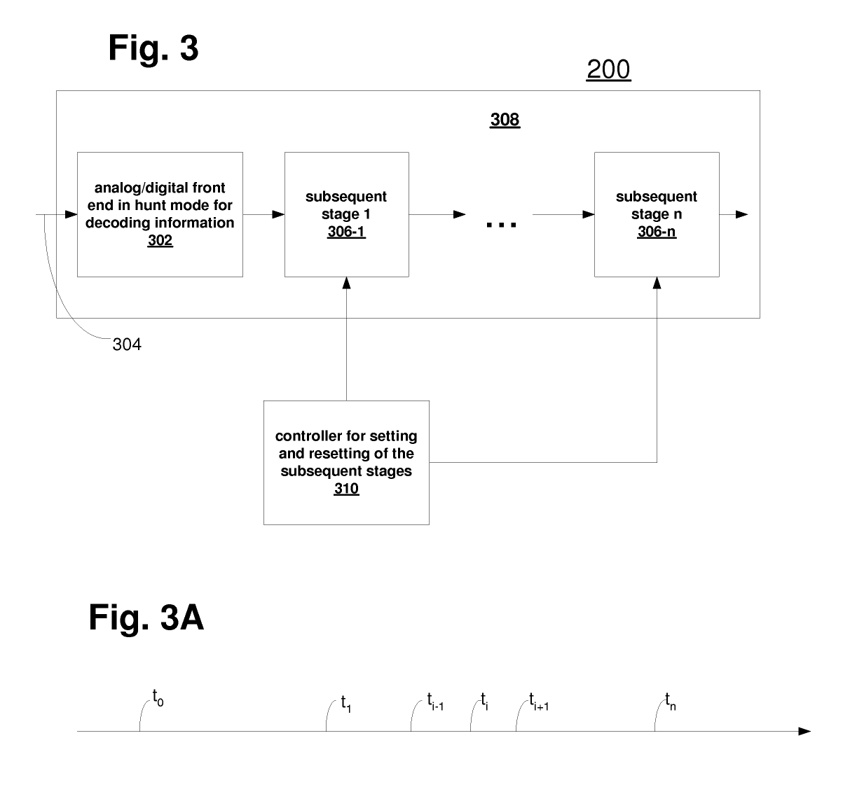

In a preferred embodiment of the present invention, the Functional blocks of the present invention is as shown in FIG. 3. An OFDM receiver 200 is comprised of multiple stages working in sequence for the processing of OFDM frames. The Receiver 200 needs to function only in the presence of a valid signal that needs to be decoded. The analog/digital front end 302 of the receiver 200 (AFE and DFE) need to be kept in a hunt or searching mode, that looks for the presence of decodable signal(s) 304. However, the subsequent stages 306-1 to 306-n following the front end 302 is not functionally required and can be powered down or switched off by keeping same in a “reset” mode therefore saving power. Each successive stage 306-i (where i is a natural number ranging between 1 to n) after recognizing a decodable stage 306-i+1 in turn enables the stage 306-i+1 or stages (i+1 to n) behind it, so the entire signal processing chain 308 is only enabled when there is at least one completely decodable frame. By way of example, at time to, the valid signal to be decoded exists for analog/digital front end 302 and not other stages, i.e. stages 306-i (i=1, 2, . . . , n). Only analog/digital front end 302 is in the decodable stage, the rest of stages are reset and not consuming significant amount of power. Similarly, at time t₁, the valid signal to be decoded exists for stage 306-1 and not other stages, i.e. stages 306-i (i=2, . . . , n). Only analog/digital front end 302 and stage 306-1 are in the decodable stage or power consuming mode, the rest of stages are reset and not consuming power. As time progresses to time tᵢ, the valid signal to be decoded exists for analog/digital front end 302 and not other stages, i.e. stages 306-i (i=1, 2, . . . , i−1, i=1, . . . , n). Only analog/digital front end 302 and stage 306-1 are in the decodable stage or power consuming mode, the rest of stages are reset and not consuming power. As time progresses to time tₙ, the valid signal to be decoded exists for analog/digital front end 302 and stage n 306-n, but not other stages, i.e. stages 306-i (i=1, 2, . . . , i−1, i, i+1, . . . , n−1). Only analog/digital front end 302 and stage 306-n are in the decodable stage or power consuming mode, the rest of stages are reset and not consuming power. Controller 310 is provided for setting and re-setting the stages. Referring to FIG. 3A, the time line of FIG. 3 is shown.

Receiver 200 incorporate techniques for Error Correction that operates by using an iterative decoding scheme which involves taking an input frame with message bits and parity bits and trying to recover an error free frame. Depending on channel conditions, the number of iterations required for recovering the original message from the received message which contains error may also vary. In a relatively error free channel, the Error correction engine can be stopped as soon as the message is decoded and further iterations are not required since the message has already been recovered. This technique is called “Partial iteration”. Partial iterative decoding saves power by turning off the state machines and sequential elements doing the decoding after the message has been recovered.

For error correction, see the commonly assigned patent application Ser. Nos. 11/557,491 to Yan Zhong, et al, and 11/767,466 to Abhiram Prabhakar et al, all of the above patent applications are hereby incorporated herein by reference.

Receiver 200 uses memory elements to store and forward data after manipulation called interleaving. These memory elements related storage are normally incorporated using DRAM device (Dynamic Random access memory). DRAM device typically require a periodic refresh cycle to retain the contents of the memory cell. In this particular implementation, the data is received and sent out of the DRAM before the cell loses the contents and hence the periodic, refresh cycle can be avoided. This avoids the overhead of having a refresh controller and also increases the throughput by avoiding refresh cycles.

Implementation also includes Passive clock gating and Active clock gating. In Passive clock gating, when sequential, digital designs want to retain the state information during the time when the primary clock is active and the primary reset is inactive, the default method used in sequential element design is to take the output of the sequential element 306-i and feed it back to the input and disable the normal input path. An alternate method to save power is to group a set of sequential elements with a common structure and disable the primary clock so as to prevent the change of state. In Active clock gating, when certain sections of the device which either has completed its current task or is not being used for implementing the current feature set, these sections also have their active primary clock gated putting these sections in a low power mode.

Physical implementation. The present invention can include Voltage and Frequency Scaling, wherein to reduce power, depending on the input data rate, the clock rate of the decoder is scaled to the minimal required clock rate needed to process the information. This is called Frequency scaling. Further, the I/O device and associated logic in different functional can be operated at different voltage threshold depending on the external device connected and the operating mode of the functional blocks. The I/O pad can also be under driven to save power. In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Terms and phrases used in this document, and variations thereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives such as “conventional,” “traditional,” “normal,” “standard,” and terms of similar meaning should not be construed as limiting the item described to a given time period or to an item available as of a given time, but instead should be read to encompass conventional, traditional, normal, or standard technologies that may be available now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

What is claimed is:

1. A method comprising the steps of:
providing a receiver based on synchronous, sequential, digital design techniques, wherein the receiver is subdivided into stages or sub-devices;
providing a primary reset, which initializes the receiver to a known state; and
providing a primary clock for changing the known state based on other inputs to the receiver.

2. The method of claim further comprising overriding the clock and holds the sequential element in the reset state.

3. The method of claim 1, wherein a memory comprises DRAM (Dynamic Random access memory) is used such that data are received and sent out of the DRAM before the DRAM cell loses the contents and hence the periodic, refresh cycle can be avoided.

4. The method of claim 1, wherein the sequential device comprises a plurality of sequentially formed stages.

5. The method of claim 5, wherein each sequentially formed stage is associated with at least one sub-device.

6. The method of claim 1, wherein the known state comprises power-on, power-off, or low power-on states respectively.

7. The method of claim 1, wherein THE plurality of sub-devices subsequent to an upstream stage is powered down in a reset mode.

8. The method of claim 1, wherein an Error correction engine is stopped as soon as a message is decoded.

9. An OFDM receiver comprising:
a primary reset, which initializes the receiver to a known state; and
a primary clock for changing the known state based on other inputs to the receiver, wherein the receiver is divided into a plurality of sub-devices forming a sequential device; and
a control signal for overriding the primary clock and holding a plurality sequential elements in a reset state.
